(19) United States
(12) Patent Application Publication
(10) Pub. No.: US 2010/0164595 A1
(43) Pub. Date: Jul. 1, 2010

(54) DOWN-CONVERTER MIXER

(75) Inventor: Francesco RADICE, Capiago Intimiano (Como) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.I., Agrate Brianza (MI) (IT)

(21) Appl. No.: 12/642,029

(22) Filed: Dec. 18, 2009

(30) Foreign Application Priority Data
Dec. 29, 2008 (IT) TO2008A000995

(51) Int. Cl. H03D 7/12

(52) U.S. Cl. 327/356

(57) ABSTRACT

A down-converter mixer may include a Gilbert cell, two transistor differential pairs, which drive output loads, and transistors defining respective tail generators coupled to common source nodes of the differential pairs. The transistors may receive a radio-frequency signal mixable with a local oscillator signal applied symmetrically between the differential pairs to produce in the loads, a signal deriving from down-converting the radio-frequency signal of an amount given by the frequency of the local oscillator signal. An inductor may be coupled to the common source nodes and which resonates with a capacitive load also coupled to the common source nodes, increases the impedance of such common nodes at the local oscillator signal frequency. The inductor may be in an open loop configuration in the absence of feedback from the mixer, and thus may be active both against noise at radio-frequency and distortion at low frequency.

### FIELD OF THE INVENTION

The present description refers to down-converter mixers. The description was developed with particular attention to the possible application to down-converter mixers of the active type.

### BACKGROUND OF THE INVENTION

Down-converter mixers, in particular of the active type, represent an important component in numerous receivers of the wireless type. As a matter of fact, such mixers allow performing a mixing operation accompanied by a gain (for example, a voltage gain) such to make the conditions required to be met by the receiver front-end low-noise amplifier less strict.

Thus, down-converter mixers of the active type improve the performance of the receiver in that they introduce a gain in the frequency conversion operation. Furthermore, while superheterodyne receivers generally require external filters for image rejection, the direct conversion architecture (or with null intermediate frequency, i.e., zero-IF) is suitable for a fully integrated implementation, which is advantageous in that it is less expensive.

However, zero-IF approaches suffer from the presence of direct current or low frequency artifacts, mainly linked to flicker noise generated by the down-converters (which is spread to a given level towards the baseband circuit) and to the second order intermodulation components (generated starting from a useful signal due to a spurious mixing action associated to the non-linear characteristics of the transistors). In particular, by propagating towards the load, flicker noise may deteriorate the overall characteristics of immunity against noise of the reception chain, in which the mixer is integrated.

Some active mixers of this type refer to the structure known as the Gilbert cell, described in B. Gilbert: “A Precise Four-Quadrant Multiplier with Subnanosecond Response”, IEEE Journal of Solid-State Circuits, Vol. 3, No. 4 (1968), pages 365-373.

FIG. 1 is a circuit diagram of a down-converter mixer of the active type based on a Gilbert cell. In particular, the diagram of FIG. 1 corresponds to an approach described in the document of H. Darabi, J. Chiu, “A Noise Cancellation Technique in RF CMOS Mixers”, Journal of Solid-State Circuits, December 2005.

The diagram of FIG. 1 is thus a cross-coupled differential amplifier including two transistor differential pairs T2, T3 and T2′, T3′ (MOSFET, in the illustrated example) coupled to two resistive loads respectively indicated with OUT+ and OUT− connected to a supply source V.

Connected to the source-drain lines (more precisely, to the common source point) of each differential pair is a “tail” generator T1, T1′, also made of a MOSFET in the example illustrated herein. The source-drain line (the drain, in the illustrated example) of the transistors T2 and T2′ is directly connected to one of the loads (respectively OUT+ for T2 and OUT− for T2′). The source-drain line (still the drain, in the illustrated example) of transistors T3 and T3′ is instead connected to the loads OUT+ and OUT− in a crossed manner, i.e. with transistor T3 connected to the load OUT−, and transistor T3′ connected to load OUT+. A capacitor C connects the source-drain lines of the transistors T2, T2′ to each other on the side of the loads OUT+ and OUT− opposite to the supply source V, while the gates of transistors T3, T3′ are connected to each other.

The general operation principle of a Gilbert cell provides that the amplitude of a differential input signal applied to the differential pairs T2, T3 and T2′, T3′ be controlled in a linear manner by a differential voltage to the gates of T1 and T1′. In the specific case of the illustrated example, a differential radio-frequency signal RF+, RF− applied between the gates of T1, T1′ may be mixed with a differential local oscillator signal LO+, LO− applied (symmetrically) between the gates of T2, T2′ (on one side) and T3, T3′ (on the other side) and down-converted by an amount corresponding to the frequency of the local oscillator signal LO. Given that this is an active circuit, the down-converted signal receivable between the load ends OUT+ and OUT− opposite to the supply source V has a voltage gain.

The diagram of FIG. 1 refers to an implementation with P-MOSFETs. The same diagram may be implemented using N-MOSFETs. Furthermore, the Gilbert cell may also be implemented using bipolar transistors. In an active mixture structure, for example, if based on a Gilbert cell with CMOS circuit, flicker noise may prevail over the desired signal. Therefore, various approaches having the aim of easing problems regarding such source of noise (also referred to as 1/f noise), have been proposed in the prior art. For example, the approach illustrated in FIG. 1 provides for associating to each differential pair (and thus to each tail generator), an impulse current generator G, G′ synchronized with the LO signal in such a manner to remove the bias at the differential pairs at the zero-crossings, thus making them temporarily de-biased. Hence, they are not capable of transferring the noise towards the load, even to the detriment of reducing the conversion gain. In other words, the approach of FIG. 1 is based on the criteria of injecting a pulsed current into the common source nodes.

Provisioning of the mixers of the type considered herein also regards IIP2 (Second-Order Intermodulation Intercept Point) problems, in particular, concerning the unwanted components at a low frequency susceptible to be generated by the spurious mixing of the components at radio frequency. As a matter of fact, two signals having frequencies f1 and f2 generate, due to the second order non-linearity of the current-voltage characteristics of the transistors, a signal at frequency f1-f2. Due to the asymmetry of the devices involved, this signal (low-frequency) may propagate towards the baseband circuits overlapping the desired signal and causing an alteration thereon. For example, in a diagram as represented in FIG. 1, the same pairs of electronic switches T2, T3 and T2′, T3′ may facilitate the conversion towards the baseband of a spurious modulation of the radio-frequency signal.

This problem has been addressed in the prior art, as shown by documents such as: M. Brandolini et al.: “A CMOS Direct Down Converter With +78 dBm Minimum IIP2 For 3-G Cell-phones”, ISSC, February 2005; M. B. Vahidfar et al.: “A New IIP2 Enhancement Technique For CMOS Down Converter Mixers”, IEEE Transactions On Circuits And Systems, December 2007; or U.S. Patent Application Publication No. 2008/0042726 to Belot et al.

### SUMMARY OF THE INVENTION

The inventor observed that approaches like the one illustrated in FIG. 1, generally suitable to allow a reduction of the noise figure (NF) even in the order of 6 dB, for particular dimensioning do not allow satisfactory results to be attained.

This event is probably due to the fact that real mixers determine a significant conversion of flicker noise in a constant manner, independently of degeneration. The diagram of FIG. 1 is based on the hypothesis whereby flicker noise is transferred to the load mainly when the differential pairs (T2, T3 and T2′, T3′) are proximal to balance situation, i.e. in proximity to the zero-crossings of the local oscillator signal LO. On the other side, when the differential pairs are unbalanced, one branch is “off” (with its noise generator likewise “off”) while the other side is completely “on” with the tail current generator (T1, T1′) which generates it in a considerable manner, allowing (supposedly) only a lower current generation by the voltage source of the flicker noise. The approach according to FIG. 1 is thus based on the criteria of operating to counter the noise in proximity to the zero-crossing of the LO signal.

Regarding this, the inventor observed that in the approach according to FIG. 1, the electronic switches of each differential pair T2, T3 and T2′, T3′ are already per se practically “off” during the transition of the local oscillator signal LO, thus, the common source point is actually only mildly discharged during the zero-crossings. In addition, the inventor observed that the noise on the common source nodes modulates the periodic nominal waveform of the local oscillator signal LO ensuring that the signal (typically a digital signal) present on such common source nodes does not have the expected nominal value, but has, overlapped, an off-set and noise component M1, M2 determined (moreover with different levels) by the switch T2, T3, T2′, T3′ involved at respective times.

Regarding the IIP2 issues, the inventor observed, for example, that the three above-mentioned approaches are far from optimal. The first approach (M. Brandolini et al.) provides for the alternating coupling of the switching quad of the two differential pairs to the RF transconductors. Apart from being suboptimal from the noise point of view, this approach generally requires a very high capacitive value, such to complicate implementation thereof.

The second approach (M. B. Vahidfar et al.) is based on the fact that the currents distorted at a low-frequency generated by the transconductors driven at radio-frequency are common mode signals, due to a second order non-linearity. When using MOSFETs, which are replicates of the radio-frequency transconductors, it is possible to allow that only the common mode signal current be injected into the pull-up resistor R. This leads to the generation of a signal useable as an error signal to be amplified before being applied to the input of the mixer so as to produce a common mode negative feedback signal. In this manner (i.e. through the RC degeneration of a pseudo-differential transconductance) the low frequency distortion currents actually absorbed by the pair of the differential switches are reduced by a factor equivalent to the loop gain.

The third approach (U.S. Patent Application Publication No. 2008/0042726 to Belot et al.) implements the same mechanism with a slightly different circuit approach adding an LC low-pass filter to address the flicker noise problem according to the methods described previously, simultaneously obtaining an even greater IIP2 factor performing an antagonist action against the residual second order distortion associated to the switching action. Thus, this approach operates in the same manner both against noise and against distortion. The capacitor of the LC filter allows effectively involving the currents of the inductors and ensures an appropriate LC filtering, preventing the inductors from being connected in series to variable impedances not well defined. Both the second and the third approaches considered herein are inherently associated to a feedback action, inevitably exposed to limitations in terms of the bandwidth and precision, in particular, regarding the matching of the devices. These approaches require, for example, the use of large surface transistors, and thus more power to operate the mixer, and they may be capable of causing criticalities in terms of stability, for example, regarding the elimination of spurious tones in the range between tens and hundreds of MHz. This aspect needs to be taken into account in Ultra Wideband (UWB) applications, or for applications in 802.11.n (WIMAX) context.

Therefore, there arises the need to provide approaches capable of overcoming the inherent drawbacks of the approaches described previously. This, in particular, with the possibility of meeting requirements, such as the IIP2 (Second-Order Intermodulation Intercept Point) specifications, may avoid, for example, having to use external filters (for example those of the Surface Acoustic Wave or SAW type). The object of the present embodiments is to provide such an approach.

According to the present embodiments, such object is attained by a down-converter mixer having the characteristics specifically referred to in the claims that follow. The claims form an integral part of the technical teaching provided herein.

An embodiment provides for increasing the output impedance of the tail generators with the aim of efficiently reducing the low frequency noise currents. An embodiment provides for having a high impedance around the frequency of the LO signal, given that the spectra of the flicker noise generators are up-converted by the switching action of the mixer, giving rise to a narrow-band modulation around the carrier frequency. An embodiment is based on increasing the impedance of the common source node at the frequency of the local oscillator (LO).

An embodiment differs from the prior art due to the baseband operation mechanism, by replacing a feedback operation on the output common mode with an open-loop mechanism. This allows exploiting an LC output network not only at radio-frequency (to eliminate flicker noise) but also at high frequency (exploiting the fact that the L is a short circuit at DC), to reduce the second order distortion. In an embodiment, the resonance of an output LC tank allows optimizing the behavior of the mixer in the presence of distortion compatibly with the use of the LC resonator, which optimizes the behavior in presence of flicker noise.

### BRIEF DESCRIPTION OF THE DRAWINGS

Now, the invention shall be described, strictly for exemplifying and non-limiting purposes, with reference to the attached representations, wherein:

FIG. 1 is a circuit diagram of a down-converter mixer in accordance with the prior art;

FIG. 2 illustrates an embodiment of a down-converter mixer in accordance with the present invention;

FIG. 3 illustrates another embodiment of a down-converter mixer in accordance with the present invention;

FIGS. 4a and 4b illustrate implementation details of the voltage buffer of FIG. 3; and

FIG. 5 illustrates another embodiment of a down-converter mixer in accordance with the present invention.

### DETAILED DESCRIPTION OF THE PREFERRED EMBODIMENTS

Illustrated in the following description are various specific details aimed at an in-depth understanding of the embodiments. The embodiments may be obtained without one or more specific details, or through other methods, components, materials, etc. In other cases, known structures, materials or operations are not shown or described in detail to avoid obscuring the various aspects of the embodiments. Reference to “an embodiment” in this description indicates that a particular configuration, structure or characteristic described regarding the embodiment is included in at least one embodiment. Hence, expressions such as “in an embodiment”, possibly present in various parts of this description do not necessarily refer to the same embodiment. Furthermore, particular configurations, structures or characteristics may be combined in any suitable manner in one or more embodiments.

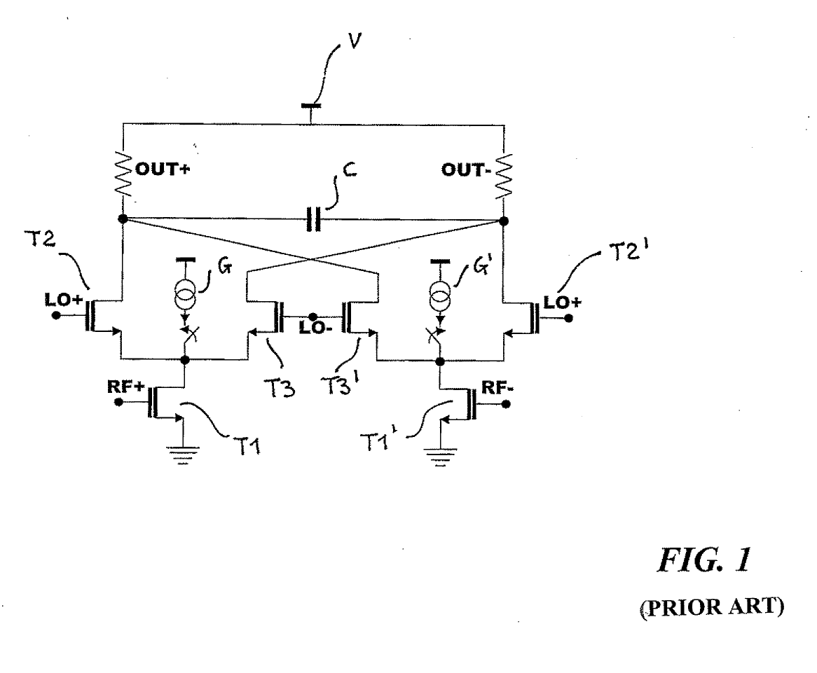

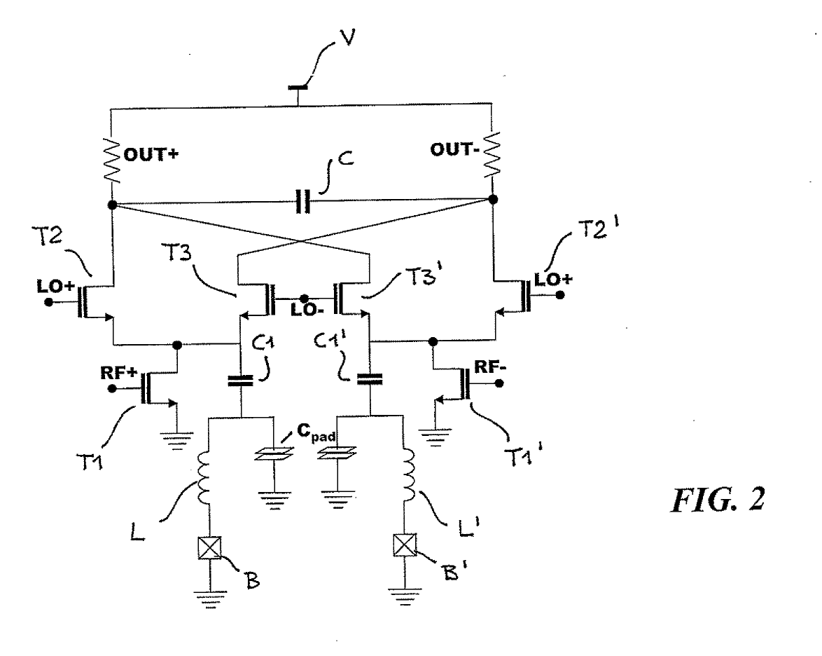

References herein are used for facilitating the reader and thus they do not define the scope of protection or the scope of the embodiments. In any case, in order to avoid useless repetitions, all the drawings attached herein, components or elements identical or equivalent to each other have been indicated with the same references. For the same reason, components or elements identical or equivalent to those described previously in connection with FIG. 1 shall not be described again in connection with FIGS. 2-5.

Though the present detailed description and the preceding introduction refer—for exemplification purposes—to field effect transistors or FET, in particular of the MOSFET type), as a general premise it should be kept in mind that the embodiments described herein may also be implemented using the bipolar technology.

The terms “source”, “gate” and “drain”, used herein and regarding FET technology, shall thus be intended as such to be integrally applied (claims included) also to the terms “emitter”, “base” and “collector”, which indicate homologous elements of a bipolar transistor. For example, the term “source-drain line” is herein intended as covering also an “emitter-collector line.”

In addition, though the embodiments described herein refer to a Gilbert cell structure (thus to a double-balanced mixer structure), the approach described herein is also applicable to mixers of the simple type, with a single cell. Thus, the approach described herein generally applies to down-converter mixers including at least one differential pair of transistors (FET or bipolar) which drives at least one load and with a transistor (FET or bipolar), defining a respective common tail generator coupled to a common node at the transistors of the at least one differential pair for controlling the current through the transistors of the at least one differential pair. The transistor defining the tail generator is suitable to receive a radio-frequency signal mixable with a local oscillator signal applied to the transistors of the at least one differential pair to produce, on the at least one load, a signal deriving from the down-conversion of the radio-frequency signal of an amount generally equivalent to the frequency of the local oscillator signal. Thus, reference to a double-balanced mixer structure (such as a Gilbert cell structure) is used for exemplifying and non-limiting purposes.

The embodiment of FIG. 2 is based on the recognition of the fact that, regarding a general structure like the one illustrated in FIG. 1, the noise may be reduced by increasing the impedance shown at the frequency of the local oscillator signal (LO) by the common node (i.e. the node where, in the illustrated embodiment, the drain of the transistor T1 (respectively T1′) is connected to the common sources of the transistors T2, T3 (respectively T2′, T3′). The embodiment illustrated in FIG. 2 obtains this result through at least one inductor interposed between the respective common source node and the ground.

In an embodiment, the inductor is selected with a value such to increase the impedance of the common source node at the level of frequency of the local oscillator signal LO. In an embodiment, this practically occurs by resonating the respective inductance with a capacitive load present at the above-mentioned common node.

The embodiment of FIG. 2 provides for the presence of two inductors L and L′, each of which is connected to the common source node of one of the differential pairs through a capacitor C1, C1′ having (also) the function of blocking the continuous component of the signal. The capacitors C1, C1′ may be integrated MOM (Metal-oxide-metal) capacitors which allow using bond-wire inductors in combination, in the entirely integrated (IC) structure, without external components.

Regarding this, in FIG. 2, references B, B′ indicate pins, i.e. the interface between the integrated circuit and the board (PCB) on which the same is mounted. The Cpad references, instead, indicate the inherent capacity of the pads, made with metal layers, where the bonding wires coming from the pins of the integrated circuit are connected.

The inductor or inductors L,L′ may also be external components. The choice is made according to the application needs depending on various factors.

For example, given that the transfer of residual noise is linked to the output resistance of the transconductors, the attainable equivalent parallel resistance value, not capable of sufficiently degenerating the electronic switches, can be taken into account. For example, the integrated inductors (with typical inductance values of 1 to 4 nH and capable of reaching 9 nH) allow obtaining a resonance factor Q of 10-15 with a parallel resistance in the order of hundreds of Ohms.

In a coordinated manner, the capacitive component at the common node is maintained low, in such a manner to similarly maintain resonance factor Q low and avoid an excessive displacement of the resonance frequency following PVT (Process-Voltage-Temperature) variations. The parasitic resistance of the connections is likewise determined in such a manner not to degrade the resonance factor Q.

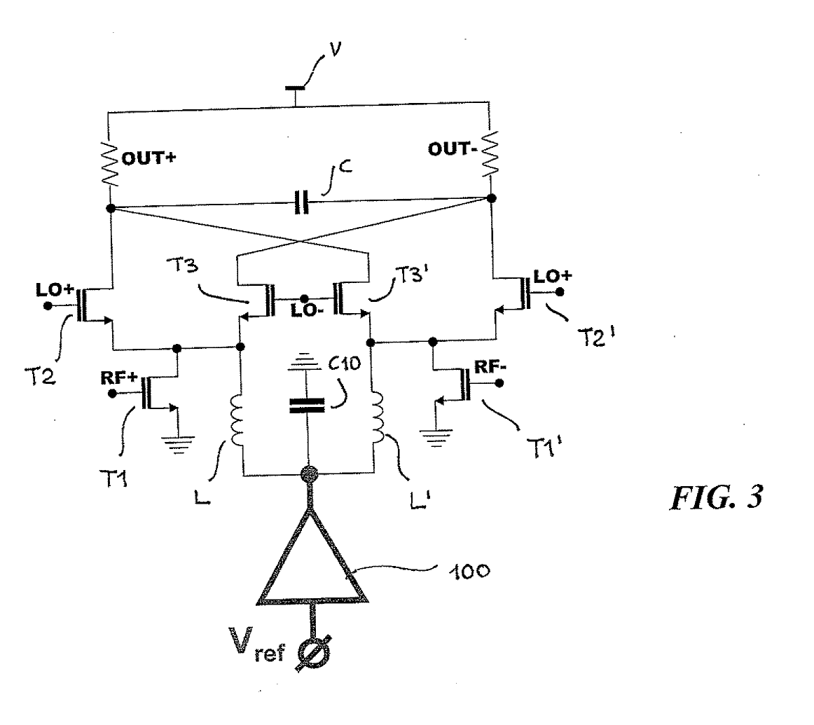

The embodiment of FIG. 3 addresses problems regarding IIP2 previously discussed by modifying the biasing scheme and providing for a voltage buffer 100 connected to both inductors L, L′ at the terminals of the latter opposite to the common source point of the differential pairs T2, T3 and T2′,T3′. In this manner, the shunt impedance may be very low even at the baseband frequencies. Hence, the currents distorted at low-frequency move towards the ground before propagating towards the pairs of electronic switches T2, T3 and T2′, T3′.

Without introducing further sources of differential noise, the function of eliminating the second order distortion not influenced by the matching degree of the devices may be obtained, in that all the unwanted current may be directed towards the ground. All this with an operation compatible with low voltages, which inherently has a very wide band due to its open loop operating principle.

A capacitor C10 connected to the common connection of the inductors L and L′ to the buffer 100 provides a ground for the radio-frequency (RF) signals. Regarding this, the presence of the buffer 100 avoids, in the presence of mismatched devices, the occurrence of a virtual short-circuit in baseband between the two common source points, with the possible presence of second order modulated components transferred in asymmetric manner (with a lower IIP2), as well as of differential components of the third order generated at radio-frequencies and down-converted (with a limitation in terms of IIP3).

In the approach illustrated in FIG. 3, the second order common mode currents are subjected to shunting by the buffer 100 at low impedance (low-Z), and possible mismatches of the devices that switch, may generate only a direct current, non-modulated, and easily rectifiable offset.

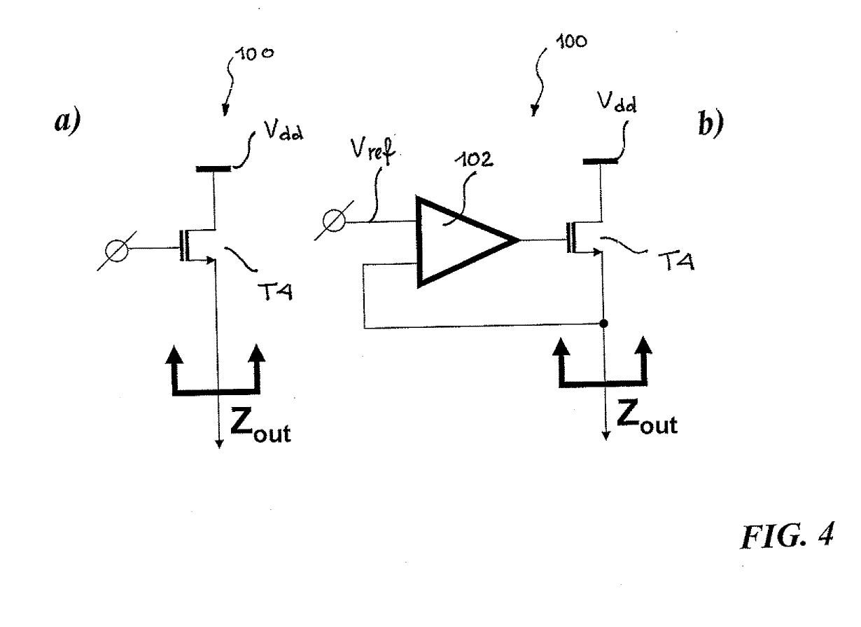

The diagrams of FIG. 4, including two parts respectively indicated with a) and b), illustrate a possible implementation of the voltage buffer 100 at low impedance. This might, for example, be the case of a MOSFET T4, whose drain is connected to the supply voltage V (capable of being very low, for example, 1 Volt) and whose gate is coupled to a voltage generator 102. The source of the MOSFET T4 has a desired Zout impedance. In the illustrated embodiment, the voltage generator 102 is a differential amplifier whose inverting input “senses” the source of T4 in feedback, and whose non-inverting input receives a reference voltage Vref (obtainable, in any known manner). With this scheme, a transconductance current of a few mA may lead to a Zout impedance at low frequency amounting to a few tens of Ohms, that is further reducible through the feedback, and thus reducing the pass-band.

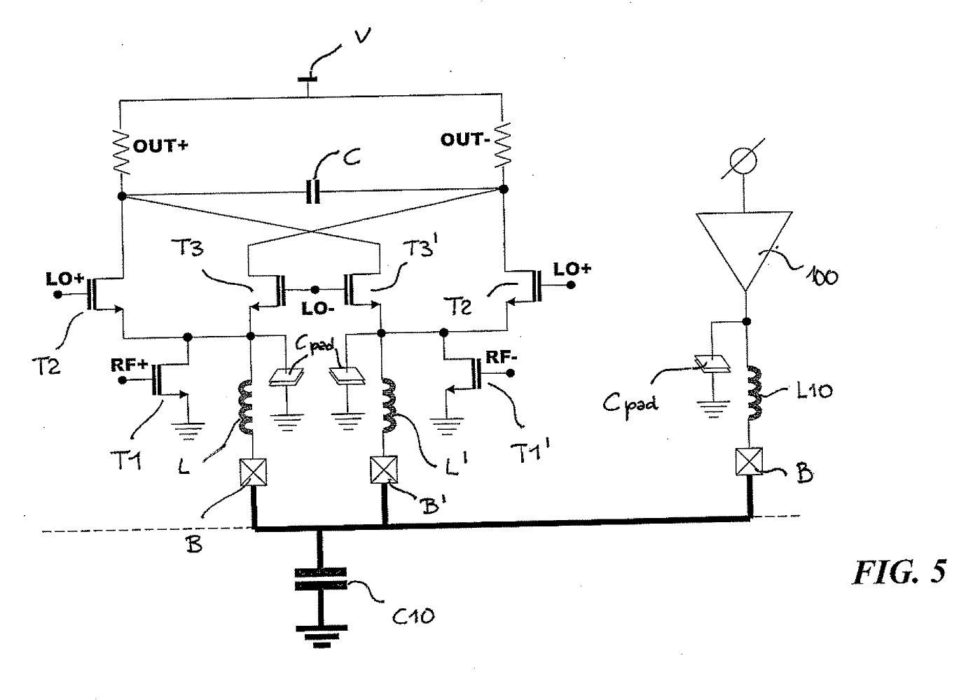

The diagram of FIG. 5 refers to a possible high-performance embodiment, which combines elements described previously with reference to FIGS. 2 and 3. In particular, in the diagram of FIG. 5, instead of the capacitors C1 and C1′ of FIG. 2, there is, like in FIG. 3, a single capacitor C10, for example, of the Hi-Q type for radio-frequencies (external or “on package”). Then, present between the inductors L, L′ and the buffer 100 (i.e. in series at the inductors L, and L′, according to a general Y-shaped configuration) is a further inductor L10, for example, of the bond-wire Hi-Q type.

In the described embodiments, the inductor or inductors L, L′; L10 is/are coupled to the common node in an open loop configuration, and in absence of feedback from the mixer. In the embodiment described, the inductor or inductors L, L′; L10 refer to the ground (possibly through a capacitive load C10 and/or a buffer 100) in a stable manner, unswitched, with an intervention mechanism, which is not modified during the operation. Thus, the inductor or inductors L, L′; L10 (and the capacitive load associated thereto) is/are active against noise at radio-frequency. At the same time, by exploiting the fact that an inductance has a decreasing impedance value with the frequency, virtually null at DC, the inductor or inductors L, L′; L10 is/are also active to reduce distortion, in particular the second order distortion.

Without prejudice to the underlying principle of the invention, the details and embodiments may vary, even significantly, with respect to what has been described herein by way of non-limiting example only, without departing from the scope of the invention as defined by the attached claims.

1-11. (canceled)

12. A down-converter mixer comprising:
at least one differential transistor pair configured to drive at least one load;
a transistor coupled to said at least one differential transistor pair via a common node and configured to control current through said at least one differential transistor pair;
said transistor configured to define a respective tail generator to receive a radio-frequency signal for mixing with a local oscillator signal, the local oscillator signal being applied to said at least one differential transistor pair to produce on the at least one load, a signal deriving from down-converting the radio-frequency signal of an amount given by a frequency of the local oscillator signal; and
at least one inductor coupled to said at least one differential transistor pair and said transistor via the common node;
said at least one inductor configured to increase an impedance of the common node at the frequency of the local oscillator signal.

13. The down-converter mixer of claim 12, wherein the down-converter mixer is configured to form an integrated circuit, and wherein said at least one inductor is at least partly integrated to said integrated circuit.

14. The down-converter mixer of claim 12 further comprising at least one capacitive load coupled to said at least one differential transistor pair, said transistor, and said at least one inductor via the common node, said at least one capacitive load configured to resonate with said at least one inductor at the frequency of the local oscillator signal to increase the impedance of the common node.

15. The down-converter mixer of claim 14, wherein the down-converter mixer is configured to form an integrated circuit, and wherein said at least one capacitive load is at least partly integrated to said integrated circuit.

16. The down-converter mixer of claim 12 further comprising a voltage buffer, said at least one inductor being interposed between the common node and said voltage buffer.

17. The down-converter mixer of claim 12, wherein said at least one inductor is coupled to the common node in an open loop configuration, in the absence of feedback from the mixer, said at least one inductor being active both against noise at radio-frequency and against distortion at low frequency.

18. The down-converter mixer of claim 12 wherein said at least one differential transistor pair comprises two differential transistor pairs in a cross-coupled configuration and configured to drive output loads, said transistor comprises a plurality of transistors defining respective tail generators, each of said plurality of transistors being coupled at a respective common node with one of said two differential transistor pairs to control current through one of said two differential transistor pairs, said plurality of transistors defining the respective tail generators to receive therebetween the radio-frequency signal for mixing with the local oscillator signal applied symmetrically between the transistors of said differential transistor pairs to produce on the output loads a differential signal deriving from down-converting the radio-frequency signal of an amount given by the frequency of the local oscillator signal, wherein said at least one inductor comprises respective inductors coupled to each respective common node to increase the impedance of each respective common node at the frequency of the local oscillator signal.

19. The down-converter mixer of claim 18, wherein the radio-frequency signal comprises a differential radio-frequency signal, and wherein the local oscillator signal comprises a differential local oscillator signal.

20. The down-converter mixer of claim 18 further comprising including two distinct capacitive loads respectively coupled to said respective inductors and configured to resonate with said respective inductors at the frequency of the local oscillator signal to increase the impedance of each respective common node.

21. The down-converter mixer of claim 18, further comprising a single capacitive load coupled to said respective inductors and configured to resonate with said respective inductors at the frequency of the local oscillator signal to increase the impedance of each respective common node.

22. The down-converter mixer of claim 21, further comprising a voltage buffer coupled to said single capacitive load and said respective inductors.

23. The down-converter mixer of claim 22 further comprising a further inductor configured in series with said respective inductors in a general Y-like configuration, said voltage buffer being coupled to said further inductor.

24. A down-converter mixer comprising:
at least one differential transistor pair configured to receive a local oscillator signal and down-convert a radio-frequency signal based thereon;
a transistor coupled to said at least one differential transistor pair and configured to receive the radio-frequency signal for mixing with the local oscillator signal; and
at least one inductor coupled to said at least one differential transistor pair and said transistor.

25. The down-converter mixer of claim 24 wherein said at least one inductor is configured to increase an impedance related to a frequency of the local oscillator signal.

26. The down-converter mixer of claim 24 further comprising at least one capacitive load coupled to said at least one differential transistor pair, said transistor, and said at least one inductor, said at least one capacitive load configured to resonate with said at least one inductor at the frequency of the local oscillator signal to increase impedance.

27. The down-converter mixer of claim 24 further comprising a voltage buffer coupled to said at least one inductor.

28. The down-converter mixer of claim 24, wherein said at least one inductor is coupled in an open loop configuration.

29. A method of making a down-converter mixer comprising:
configuring at least one differential transistor pair to receive a local oscillator signal and down-convert a radio-frequency signal based thereon;
coupling a transistor to the at least one differential transistor pair and configuring the transistor to receive the radio-frequency signal for mixing with the local oscillator signal; and
coupling at least one inductor to the at least one differential transistor pair and the transistor.

30. The method of claim 29 further comprising configuring the at least one inductor to increase an impedance related to a frequency of the local oscillator signal.

31. The method of claim 29 further comprising coupling at least one capacitive load to the at least one differential transistor pair, the transistor, and the at least one inductor, and configuring the at least one capacitive load to resonate with the at least one inductor at the frequency of the local oscillator signal to increase an impedance.

32. The method of claim 29, wherein coupling the at least one inductor comprises coupling the at least one inductor in an open loop configuration.
